(19) United States
(12) Patent Application Publication
(10) Pub. No.: US 2026/0114249 A1
(43) Pub. Date: Apr. 23, 2026

(54) HEMT (High Electron Mobility Transistor) And Method Therefor

(71) Applicant: ThinSiC Inc., Santa Clara, CA (US)

(72) Inventors: Tirunelveli Subramaniam Ravi, San Jose, CA (US); Jinho Seo, Saratoga, CA (US); Bishnu Prasanna Gogoi, Scottsdale, AZ (US)

(73) Assignee: ThinSiC Inc., Santa Clara, CA (US)

(21) Appl. No.: 18/923,989

(22) Filed: Oct. 23, 2024

(51) Int. Cl. H01L 21/78; H01L 21/02; H01L 21/683; H01L 29/20; H01L 29/40; H01L 29/66; H01L 29/778

(52) U.S. Cl. CPC H10P 95/112; H10D 30/015; H10D 30/475; H10D 62/8503; H10D 64/111; H10P 14/2904; H10P 14/3216; H10P 14/3416; H10P 54/00; H10P 72/7402; H10P 72/7416

(57) ABSTRACT

A heterogeneous epitaxial structure formed on a SiC (silicon carbide) substrate. An intermediate layer comprising AIN is formed overlying the SiC substrate. The surface of the intermediate layer comprises AIN formed by lateral epitaxial growth. The lateral epitaxial growth merges to form the surface comprising a MELO layer (merged epitaxial lateral overgrowth). The intermediate layer includes a carbon layer underlying the MELO layer. At least one device layer comprising GaN (gallium nitride) is formed overlying the surface of the intermediate layer in which one or more semiconductor devices are formed. The carbon layer is heated to fracture portions of the intermediate layer to separate the SiC substrate from the intermediate layer. The SiC substrate is not consumed by the separation thereby allowing perpetual reuse in semiconductor wafer processing.

### FIELD

This invention relates to semiconductor device on silicon carbide manufacture, and in particular to the formation of a hetero epitaxial structure.

### BACKGROUND

The use of wide bandgap (WBG) semiconductors has increased dramatically in recent years in power electronics. Their ability to operate efficiently at higher voltages, powers, temperatures, and switching frequencies has enabled reduced cooling requirements, lower part counts, and the use of smaller passive components. WBG-based power electronics can further reduce the footprint and potentially the system cost of various renewable energy electrical equipment such as motor drivers and inverters.

Among the WBG semiconductors for power electronics, Silicon Carbide (SiC) has now been increasingly used for high voltage drivers (>1200 V) whereas Gallium Nitride (GaN) has been experiencing increased use in both higher power and higher frequency applications. From the substrate standpoint, 4H-Silicon carbide (SiC) Single Crystal Substrates have been used for both SiC and GaN devices since SiC and GaN epitaxial layers can be grown with reduced defects on SiC substrates. The SiC substrate is a significant portion of the cost to manufacture semiconductor devices. While the SiC substrate quality has dramatically improved in the recent years, the cost has not come down since substrate fabrication is a complex process starting with vapor phase ingot growth followed by ingot cropping, then wire sawing of individual wafers, and finally grinding and polishing of the substrate, and as of now, there has been no proven practical method to eliminate any of these foregoing steps.

The manufacture of WBG semiconductors is expanding as WBG devices are being used in many applications that have a mass market. Market and device applications are becoming more diverse as the cost of WBG devices is reduced. For example, semiconductor substrates for WBG semiconductors are being produced that use high currents that require large die sizes. Defects will play a role in the larger die sizes as they can reduce die yields. Therefore, to maximize die yield, any cost reduction activity regarding the substrate is paramount while also maintaining low defect densities in the active epitaxial layer. In particular, GaN substrates are small in size compared to other substrates and the cost to manufacture a high quality GaN substrate of the same size as SiC substrate is not competitive at this time.

Accordingly, it is desirable to produce a process in which GaN devices can be manufactured at low cost with improved performance and reliability.

### BRIEF DESCRIPTION OF THE DRAWINGS

Various features of the system are set forth with particularity in the appended claims. The embodiments herein, can be understood by reference to the following description, taken in conjunction with the accompanying drawings, in which:

FIG. 1 is an illustration of a silicon carbide (SiC) substrate in accordance with an example embodiment;

FIG. 2 is an illustration of a first layer of a second material overlying the SiC substrate in accordance with an example embodiment;

FIG. 3 is an illustration of a hard mask layer overlying the first layer in accordance with an example embodiment;

FIG. 4 is an illustration of a plurality of openings formed in the hard mask layer in accordance with an example embodiment;

FIG. 5 is an illustration of openings formed in the first layer in accordance with an example embodiment;

FIG. 6 is an illustration of a plurality of pillars formed in the first layer in accordance with an example embodiment;

FIG. 7 is an illustration of a refill layer formed over the plurality of pillars in accordance with an example embodiment;

FIG. 8 is an illustration of a mask layer formed between the plurality of pillars in accordance with an example embodiment;

FIG. 9 is an illustration of a first epitaxial layer of Aluminum Nitride formed overlying a patterned AIN layer in accordance with an example embodiment;

FIG. 10 is an illustration of epitaxial layers grown overlying the first epitaxial layer in accordance with an example embodiment;

FIG. 11 is an illustration of a metal gate layer deposited over the epitaxial layer of pGaN, in accordance with an example embodiment;

FIG. 12 is an illustration of a transistor gate formed with a patterned metal gate and a patterned pGaN layer in accordance with an example embodiment;

FIG. 13 is an illustration of an insulating layer deposited over the transistor gate formed with the patterned metal gate and the patterned pGaN layer in accordance with an example embodiment;

FIG. 14 is an illustration of contact openings formed in the insulating layer in accordance with an example embodiment;

FIG. 15 is an illustration of metal contacts coupled to the source and drain regions of the HEMT in accordance with an example embodiment;

FIG. 16 is an illustration of an insulating layer formed over the source contacts and the drain contacts in accordance with an example embodiment;

FIG. 17 is an illustration of second source metal contacts and second drain metal contacts formed in accordance with an example embodiment;

FIG. 18 is an illustration of a plurality of GaN devices formed in accordance with an example embodiment;

FIG. 19 is an illustration of a singulation layer formed over the plurality of GaN devices in accordance with an example embodiment;

FIG. 20 is an illustration of a carrier substrate temporarily coupled to the SiC substrate with the plurality of GaN devices in accordance with an example embodiment;

FIG. 21 is an illustration of plurality of GaN devices exfoliated from the substrate in accordance with an example embodiment;

FIG. 22 is an illustration of the exfoliated device comprising the plurality of GaN devices attached to the carrier substrate in accordance with an example embodiment;

FIG. 23 is an illustration of the exfoliated device comprising a plurality of GaN devices temporarily attached to the carrier substrate in accordance with an example embodiment;

FIG. 24 is an illustration of the exfoliated device comprising a plurality of GaN devices after being separated from the carrier substrate in accordance with an example embodiment;

FIG. 25 is an illustration of the plurality of GaN devices after singulation in accordance with an example embodiment;

FIG. 26 is an illustration of the plurality of GaN devices after removal from the dicing tape in accordance with an example embodiment;

FIG. 27 is an illustration of a separated SiC substrate after the exfoliation process in accordance with an example embodiment; and

FIG. 28 is an illustration of a new SiC substrate in accordance with an example embodiment.

### DETAILED DESCRIPTION

The following description of embodiment(s) is merely illustrative in nature and is in no way intended to limit the invention, its application, or uses.

For simplicity and clarity of the illustration(s), elements in the figures are not necessarily to scale, are only schematic, are non-limiting, and the same reference numbers in different figures denote the same elements, unless stated otherwise.

Additionally, descriptions and details of well-known steps and elements are omitted for simplicity of the description. Notice that once an item is defined in one figure, it may not be discussed or further defined in the following figures.

The terms “first”, “second”, “third” and the like in the Claims or/and in the Detailed Description are used for distinguishing between similar elements and not necessarily for describing a sequence, either temporally, spatially, in ranking or in any other manner. It is to be understood that the terms so used are interchangeable under appropriate circumstances and that the embodiments described herein are capable of operation in other sequences than described or illustrated.

Processes, techniques, apparatus, and materials as known by one of ordinary skill in the art may not be discussed in detail but are intended to be part of the enabling description where appropriate.

While the specification concludes with claims defining the features of the invention that are regarded as novel, it is believed that the invention will be better understood from a consideration of the following description in conjunction with the drawing figures, in which like reference numerals are carried forward.

A formation of a plurality of semiconductor devices using wide band gap materials is described herein below. A silicon carbide (SiC) substrate is used for the formation of a plurality of Gallium Nitride (GaN) devices with superior electrical characteristics, good yield, high reliability, better thermal performance and lower cost. The invention is described with an example embodiment of a High Electron Mobility Transistor (HEMT) formed using GaN layers overlying a silicon carbide substrate. While a HEMT has been used in the example embodiment, other devices can also be formed in the GaN layers overlying the silicon carbide substrate, as will be evident to those skilled in the art. Thus, other semiconductor devices that can be formed with the current invention includes RF(Radio Frequency) GaN devices, LED (Light Emitting Diodes), UV-C LED (Ultraviolet Light Emitting Diodes) among other devices.

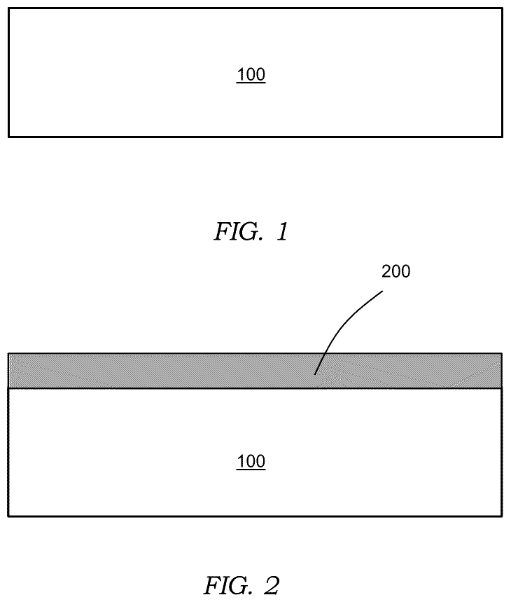

FIG. 1 is an illustration of a Silicon Carbide (SiC) substrate 100 in accordance with an example embodiment. Silicon carbide substrate 100 is a wide bandgap semiconductor material used for the fabrication of semiconductor devices. SiC substrate 100 is an example of a semiconductor substrate used for the fabrication of semiconductor devices. In the example embodiment, SiC substrate 100 is a silicon carbide (SiC) wafer that is typically a heavily doped off-cut by 4 degrees or a semi-insulated on-axis of <0001>. Silicon carbide substrate 100 may be called substrate 100 or SiC substrate 100 herein after.

In one embodiment, SiC substrate 100 is a crystalline 4H silicon carbide wafer with a preferred crystalline orientation of <0001>. In one embodiment, SiC substrate 100 is in the range of (300-500 microns) in thickness. In one embodiment, SiC substrate 100 may be a single side polished or double side polished wafer and can be considered as the parent wafer, for considerations that are described in subsequent process steps in the implementation of the current invention. In one embodiment, SiC substrate 100 is the basic platform on which the example embodiment is implemented to support the process flow in accordance with the current invention. In one embodiment, SiC substrate 100 is a reusable semiconductor substrate that is used for fabrication of a plurality of semiconductor devices two or more times in accordance with the current invention. In one embodiment, the process disclosed herein below enables the perpetual reuse of SiC substrate 100 thereby providing substantial cost savings in the fabrication of semiconductor devices since SiC substrate 100 is a substantial portion of the overall cost in the fabrication process.

FIG. 2 is an illustration of a first layer 200 of a second material overlying SiC substrate 100 in accordance with an example embodiment. First layer 200 of a second material is grown overlying the entire surface of SiC substrate 100 and has a different lattice constant than material of SiC substrate 100 but is sufficiently close in the lattice constant (less than 5%) to form a single crystal layer. In one embodiment, first layer 200 is grown overlying the surface of SiC substrate 100 using an epitaxial growth process.

In the example embodiment, first layer 200 comprises single crystal Aluminum Nitride (AIN) overlying SiC substrate 100. In the example embodiment, first layer 200 comprising AIN is grown using MOVPE (Metal Organic Vapor Phase Epitaxy), HT-MOVPE (High Temperature Metal Organic Vapor Phase Epitaxy) among other methods. In the example embodiment, first layer 200 comprising AIN is grown using HT-MOVPE with TMAI (TriMethylAluminum) and ammonia (NH₃) as the precursor gases in the reactor. In the example embodiment, the gas flow rates, gas ratio between TMAI/NH₃, temperature, pressure and other parameters are controlled to form an epitaxial layer of first layer 200 comprising AIN overlying SiC substrate 100. In the example embodiment, a thickness of first layer 200 comprising AIN is between (1-3) micrometers. In the growth of first layer 200 overlying the surface of SiC substrate 100, there are dislocation defects formed due to the lattice constant mismatch as well as the surface and crystalline defects in the underlying substrate. In the example embodiment, first layer 200 comprising AIN, there is a density of defects such as dislocations which can cause device performance degradation and reliability issues. Accordingly, it is necessary to develop techniques to reduce the density of defects in first layer 200 below an acceptable defect density (10⁹/cm²) for reliable device performance.

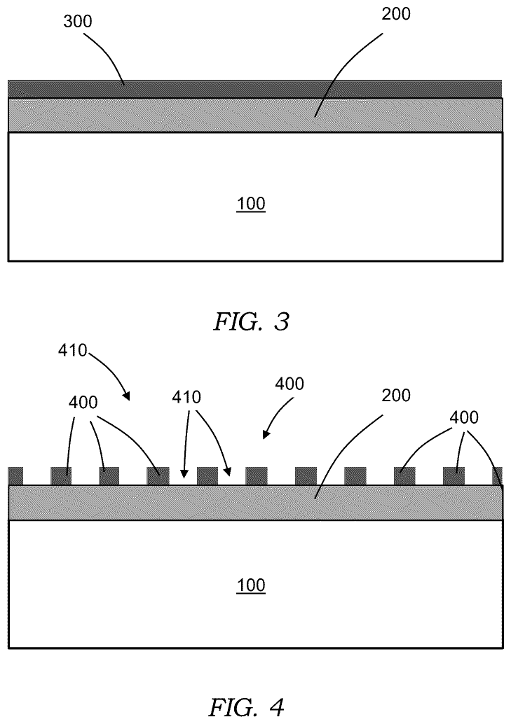

FIG. 3 is an illustration of a hard mask layer 300 overlying first layer 200 in accordance with an example embodiment. Hard mask layer 300 is deposited over the entire surface of first layer 200. Hard mask layer 300 is deposited using techniques such as CVD (Chemical Vapor Deposition), LPCVD (Low Pressure Chemical Vapor Deposition), PECVD (Plasma Enhanced Chemical Vapor Deposition), APCVD (Atmospheric Pressure Chemical Vapor Deposition), SACVD (Sub Atmospheric Chemical Vapor Deposition) among other techniques. PVD (Physical Vapor Deposition), or ALD (Atomic layer Deposition) may also be used for forming hard mask layer 300. In the example implementation, hard mask layer 300 comprises PECVD (Plasma Enhanced Chemical Vapor Deposition) silicon oxide. The thickness of silicon oxide hard mask layer 300 is selected based on the requirements of subsequent processing steps as described in the example implementation and is in the range of (100-3000) nm. The thickness of hard mask layer 300 is determined by the specific requirements of the implementation and is well known to those skilled in the art. In another embodiment, more than one hard mask layer may be used in the implementation of the semiconductor devices that are formed using subsequent fabrication steps.

FIG. 4 is an illustration of a plurality of openings 410 formed in hard mask layer 300 of FIG. 3 in accordance with an example embodiment. In one embodiment, hard mask layer 300 of FIG. 3 is deposited overlying the entire surface of first layer 200 overlying SiC substrate 100 and is patterned to subsequently form plurality of openings 410 that expose areas of a surface of first layer 200. A remaining patterned hard mask 400 protects unexposed surface of first layer 200 after the patterning process. Plurality of openings 410 are formed in hard mask layer 300 of FIG. 3 by using methods of lithography and etching techniques commonly used in the semiconductor industry. In one embodiment, remaining patterned hard mask 400 is left in areas to protect first layer 200 from being etched. The shape of plurality of openings 410 are determined by the requirements of epitaxial growth in subsequent steps in the implementation of the example embodiment. In one embodiment, plurality of openings 410 may be in the shape of squares, circles, or rectangles. In another embodiment, plurality of openings 410 may be in the shape of triangles, hexagons or diamonds. The size of plurality of openings 410 may be in the range of (20-500) nm and determined by the requirements of epitaxial overgrowth in the subsequent steps of fabrication of the example device. In one embodiment, spacing between adjacent openings of plurality of openings 410 is determined by the requirements of epitaxial overgrowth in the subsequent steps of fabrication of the example device and can be in the range of 500 nanometers to 5 micrometers. Plurality of openings 410 are generated in hard mask layer 300 of FIG. 3 by using lithography techniques that are well known to those skilled in the art. In one embodiment, plurality of openings 410 are implemented using optical lithography using UV (Ultra Violet), DUV (Deep Ultra Violet) or EUV (Extreme Ultra Violet) light sources. In another embodiment, plurality of openings 410 are implemented using an electron beam direct write technique or laser beam direct write technique. In yet another embodiment, plurality of openings 410 are implemented using Nano-Imprint Lithography (NIL). In one embodiment, plurality of openings 410 are implemented using a stepper or scanner. In another embodiment, plurality of openings 410 are implemented using a contact aligner or projection aligner.

In one example embodiment, plurality of openings 410 are formed by first coating a surface of hard mask layer 300 of FIG. 3 with a photosensitive layer of photoresist, which may be positive or negative in its chemistry. In the example embodiment, positive photoresist is used in coating the surface of hard mask layer 300 of FIG. 3. A stepper is used to transfer the pattern of plurality of openings 410 on to the positive photoresist layer using chemistries that are well known to those skilled in the art. The choice of the photoresist layer, thickness of the photoresist layer, the exposure and develop times for the subsequent chemical steps are well known to those skilled in the art and determined by the requirements of accurate pattern transfer from the photoresist layer to hard mask layer 300 of FIG. 3 to subsequently form plurality of openings 410 and leaving patterned hard mask 400. The stepper transfers the pattern of plurality of openings 410 to cover the surface of hard mask layer 300 of FIG. 3 overlying first layer 200 of FIG. 2 comprising AIN (Aluminum Nitride). Special fiducials may be used in the stepper mask to ensure that the stitching accuracy is optimized from field to field during the pattern transfer process.

After the pattern transfer is completed using lithography with a stepper, the next step is the patterning of hard mask layer 300 of FIG. 3 using etching techniques to selectively remove the hard mask layer 300 of FIG. 3 overlying first layer 200 thereby leaving patterned hard mask 400 overlying first layer 200. The selective removal of hard mask layer 300 of FIG. 3 to form patterned hard mask 400 may use Reactive Ion Etching (RIE). Different gases for the plasma etching may be used to selectively remove the portions of hard mask layer 300 of FIG. 3 exposed by the patterned photoresist. The choice of gases for the RIE is determined by hard mask layer 300 of FIG. 3 used in the implementation. In the example embodiment, silicon oxide is used as hard mask layer 300 of FIG. 3, and fluorine-based chemistries such as SF₆, CF₄, CHF₃, and other gases may be used in the RIE. Accordingly, in the example embodiment with silicon oxide as hard mask layer 300 of FIG. 3, plurality of openings 410 are etched in hard mask layer 300 of FIG. 3 using a fluorine-based chemistry that exposes the surface of first layer 200 comprising AIN. Patterned hard mask 400 remains in areas overlying the surface of first layer 200 comprising AIN to protect or mask the surface of first layer 200 from etching.

After patterning hard mask layer 300 of FIG. 3, the photoresist is stripped using techniques well known to those skilled in the art and may be dry, wet or a combination of dry and wet processing.

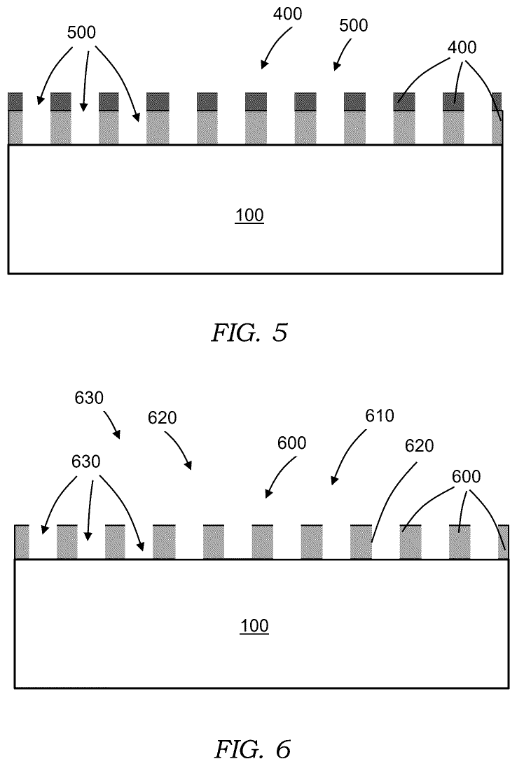

FIG. 5 is an illustration of openings 500 formed in first layer 200 in accordance with an example embodiment. Openings 500 are formed after hard mask layer 300 of FIG. 3 is etched to form plurality of openings 410 in FIG. 4. In one embodiment, the surface of first layer 200 is exposed by plurality of openings 410 of FIG. 4 and then etched to form openings 500 using RIE (Reactive Ion Etching). In one embodiment, first layer 200 comprising AIN (Aluminum Nitride) is etched using patterned hard mask 400 to form openings 500 with an aspect ratio that is determined by the requirements of epitaxial growth in subsequent processing of the example device. In one embodiment, first layer 200 comprising AIN is etched using a chlorine chemistry with Cl₂, BCI₃, Argon among other gases to form openings 500 in first layer 200. The process parameters such as gas flows, gas ratios, pressure, power, bias voltage among other process parameters are changed to determine the depth and profile of openings 500 in first layer 200. It should be noted that other materials may be similarly used for first layer 200 as disclosed herein above. In one embodiment, an inductively coupled plasma (ICP) with high density may also be used to form openings 500 in first layer 200 comprising AIN. In another embodiment, the patterned photoresist layer used to form plurality of openings 410 with patterned hard mask 400 is not stripped and may be retained during the patterning of first layer 200 using RIE to form openings 500.

FIG. 6 is an illustration of a plurality of pillars 600 formed in first layer 200 in accordance with an example embodiment. Plurality of pillars 600 are shown after the removal of patterned hard mask 400 of FIG. 5 and after formation of openings 500 of FIG. 5 in first layer 200. In an example embodiment, patterned hard mask 400 of FIG. 5 is removed by using wet or dry chemical etching and is determined by the choice of hard mask layer material. In the example embodiment, patterned hard mask 400 of FIG. 5 comprises a PECVD silicon oxide layer that is removed using a wet chemistry of BHF (Buffered Hydrofluoric Acid). Other solutions for etching PECVD silicon oxide may include HF (Hydrofluoric Acid) in various dilutions in water. In the example embodiment, the formation of plurality of pillars 600 in first layer 200 of FIG. 2 results in a patterned aluminum nitride (AIN) layer 610 overlying SiC substrate 100. In one embodiment, portions of SiC substrate 100 are exposed between plurality of pillars 600.

In the example embodiment, patterned AIN layer 610 overlying SiC substrate 100 is cleaned in preparation for the next step in the fabrication of the example device. In one embodiment, the pattern of plurality of pillars 600 are shaped as to be circular, triangular, rectangular, hexagonal, truncated pyramidal, conical, or a point, to expose crystal planes that facilitate high quality epitaxial overgrowth with low defect density in subsequent processing steps in accordance with the current invention. Plurality of pillars 600 has a height 620 and spacing 630 between adjacent pillars. In one embodiment, plurality of pillars 600 has height 620 in the range of (0.4-4) micrometers. In one embodiment, plurality of pillars 600 has spacing 630 between adjacent pillars in the range of (0.4-4) micrometers. The height 620 of plurality of pillars 600 and spacing 630 between adjacent pillars of plurality of pillars 600 are determined by the requirements of AIN (Aluminum Nitride) epitaxy as subsequently described herein. In one embodiment, if the patterned photoresist layer is used along with patterned hard mask 400 of FIG. 4 to form openings 500 in first layer 200 using RIE, the photoresist layer is stripped first after the RIE using an oxygen plasma before removing patterned hard mask 400 of FIG. 5 using BHF etching leaving plurality of pillars 600 formed in patterned AIN layer 610. In one embodiment, plurality of pillars 600 is formed over the entire surface of substrate 100.

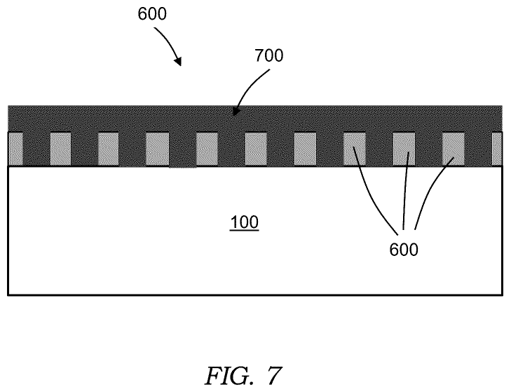

FIG. 7 is an illustration of a refill layer 700 formed over plurality of pillars 600 in accordance with an example embodiment. In one embodiment, refill layer 700 is formed overlying plurality of pillars 600 in patterned AIN layer 610 and in openings 500 of FIG. 5 after removal of patterned hard mask 400 of FIG. 4.

Refill layer 700 is formed on surface of patterned AIN layer 610 with plurality of pillars 600 and on exposed portions of surface of SiC substrate 100 in openings 500 of FIG. 5 after removal of patterned hard mask 400 of FIG. 4.

In general, refill layer 700 comprises a material or materials configured to stress or fracture plurality of pillars 600 in a subsequent step described in detail herein below. In one embodiment, refill layer 700 is a carbon layer. In another embodiment, refill layer 700 comprises tantalum carbide. In another embodiment, refill layer 700 is a polymer layer that is deposited and then subsequently converted into a carbon layer. In general, refill layer 700 is a layer that can be subsequently targeted by a laser specifically after further wafer processing is performed. For example, refill layer 700 can be selectively heated by a laser in a subsequent step which will be described in further detail herein below. In one embodiment, the laser will penetrate through SiC substrate 100 or other layers overlying or underlying SiC substrate 100 (with no effect to SiC substrate 100 or other layers used in the formation of the semiconductor devices) and be absorbed by refill layer 700.

Refill layer 700 can be formed over plurality of pillars 600 in patterned AIN layer 610 and in openings 500 of FIG. 5 after removal of patterned hard mask 400 of FIG. 4 using different methods and processes.

In one embodiment, refill layer 700 may be formed by spin coating a polymer layer and then subsequently converting it into a carbon layer by pyrolysis in an inert environment. In another embodiment, refill layer 700 may be formed by CVD (Chemical Vapor Deposition) of a polymer layer such as Parylene and subsequently converting the deposited polymer layer into carbon by heating it at a high temperature (900-1400)° C. in an inert environment such as nitrogen. In another embodiment, refill layer 700 may be formed by sputter deposition using a carbon target. Other methods of carbon deposition may include CVD (chemical vapor deposition) or ALD (Atomic layer Deposition) to form refill layer 700.

In an example embodiment, refill layer 700 is formed by spin coating a photoresist layer. The photoresist layer may be a positive polarity or negative photoresist. The choice of thickness of the photoresist layer is determined by the height 620 of plurality of pillars 600 and the final thickness of refill layer 700 required by the process. The final thickness of the spin-coated photoresist is determined by the choice of the viscosity of the photoresist and the spread and spin speed during the dispense of the photoresist. The spin-coated photoresist is then baked in a nitrogen environment at a temperature of (90-120)° C. to drive out solvents. In the pyrolysis process, plurality of pillars 600 coated with a photoresist layer is placed in a furnace and heated to (900-1400)° C. in an inert environment of nitrogen or in forming gas (nitrogen with hydrogen) to convert the spin-coated photoresist to carbon. During the pyrolysis process, the spin coated photoresist layer is converted into carbon while undergoing volumetric shrinkage. In the example embodiment, the pyrolysis process converts the spin-coated photoresist to carbon while also shrinking to form refill layer 700. In another embodiment, the spin-coated photoresist layer thickness may be modified by etching in an oxygen plasma after the spin-coating and prior to the pyrolysis process. In another embodiment, multiple layers of photoresist and pyrolysis may be used to convert refill layer 700 into a carbon layer. In another embodiment, refill layer 700 may comprise polyimide that is spin coated or spray coated over plurality of pillars 600 in patterned AIN layer 610 and in openings 500 of FIG. 5 after removal of patterned hard mask 400 of FIG. 4 and then subsequently converted into a carbon layer by pyrolysis.

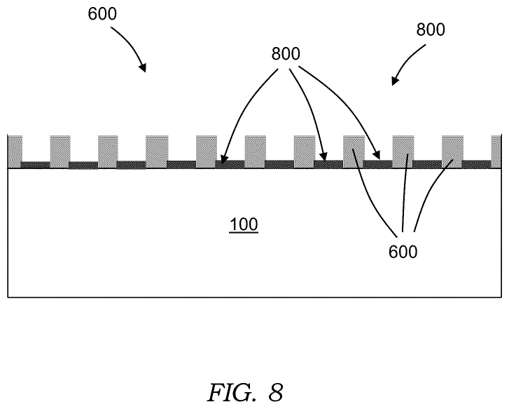

FIG. 8 is an illustration of a mask layer 800 formed between plurality of pillars 600 in accordance with an example embodiment. Mask layer 800 is comprised of a material or materials that is different from patterned AIN layer 610 and SiC substrate 100 and is used in the epitaxial growth processes of patterned AIN layer 610 overlying SiC substrate 100 as will be subsequently described herein below. Mask layer 800 is formed overlying exposed portions of SiC substrate 100 between plurality of pillars 600 comprising patterned AIN layer 610.

In general, mask layer 800 is formed by reducing the thickness of refill layer 700 of FIG. 7. In one embodiment, mask layer 800 is formed from refill layer 700 which is a carbon layer that is deposited and then reduced in height using RIE (Reactive Ion Etching).

In one embodiment, a height of refill layer 700 of FIG. 7 is reduced to a predetermined height to form mask layer 800. The predetermined height of mask layer 800 is below surface of patterned AIN layer 610 and below height 620 of plurality of pillars 600 of FIG. 6. The predetermined height is achieved by RIE using oxygen, argon and other gases, as well known to those skilled in the art. In one embodiment, the predetermined height of mask layer 800 is in a range of (300-1000) nanometers (nm). In one embodiment, mask layer 800 comprises tantalum carbide that is deposited and then etched to a thickness less than height 620 of plurality of pillars 600 in patterned AIN layer 610 of FIG. 6.

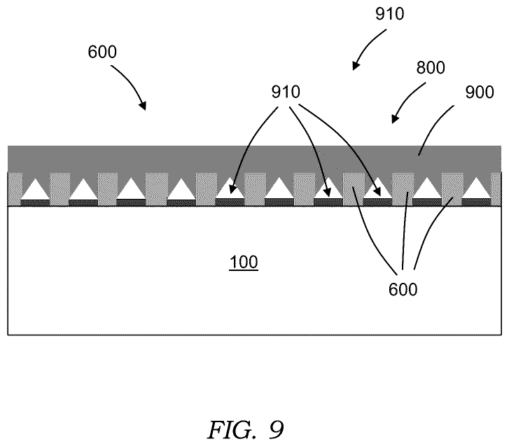

FIG. 9 is an illustration of a first epitaxial layer 900 of Aluminum Nitride formed overlying patterned AIN layer 610 of FIG. 6 in accordance with an example embodiment. In the example embodiment, SiC substrate 100 with plurality of pillars 600 and mask layer 800 of FIG. 8 is placed in an epitaxial reactor to form first epitaxial layer 900 of AIN. Different methods of growing first epitaxial layer 900 of AIN over plurality of pillars 600 of AIN may be used. These methods of growing first epitaxial layer 900 may be MOCVD, MBE, HT-MOVPE among other methods. In an example embodiment, the method of HT-MOVPE is used to grow first epitaxial layer 900 of AIN. The growth conditions in the epitaxial reactor are controlled such that epitaxial lateral overgrowth of AIN from the sidewalls of plurality of pillars 600 of FIG. 6 merge to form a merged epitaxial lateral overgrowth layer with a continuous first epitaxial layer 900 of AIN overlying substrate 100. In the epitaxial reactor, growth conditions of temperature, pressure, gas flow rates and ratios of precursor gases such as TMAI (TriMethyl Aluminum) and ammonia, as well as carrier gases such as hydrogen and nitrogen, are modulated to enhance epitaxial lateral overgrowth of first epitaxial layer 900 to merge between adjacent pillars of plurality of pillars 600. The epitaxial lateral overgrowth of first epitaxial layer 900 extends from sidewalls of plurality of pillars 600 thereby coalescing to form a continuous epitaxial layer of AIN overlying plurality of pillars 600 and the space between adjacent pillars of plurality of pillars 600. In one embodiment, the growth of first epitaxial layer 900 of AIN produces at least one void 910 underlying the merged epitaxial lateral growth of first epitaxial layer 900 between adjacent pillars of plurality of pillars 600. In the example embodiment, a plurality of voids 910 are enclosed in the space between first epitaxial layer 900 and mask layer 800 of FIG. 8. In another embodiment, the epitaxial lateral overgrowth of AIN encloses a plurality of voids 910 over a polycrystalline layer of AIN overlying mask layer 800 of FIG. 8.

In the example embodiment, first epitaxial layer 900 of AIN formed by epitaxial lateral overgrowth of AIN from plurality of pillars 600 of FIG. 6 overlying patterned AIN layer 610 of FIG. 6 results in reduction of density of defects in first epitaxial layer 900 of AIN. By allowing the epitaxial lateral overgrowth from the sidewalls of plurality of pillars 600 of FIG. 6, defects such as threading dislocations and edge dislocations are reduced resulting in first epitaxial layer 900 with higher epi quality and lower defect density. The growth of first epitaxial layer 900 with epitaxial lateral overgrowth may reduce the density of defects by an order of magnitude less than the density of defects in patterned AIN layer 610 of FIG. 6.

The epitaxial lateral overgrowth of first epitaxial layer 900 over patterned AIN layer 610 of FIG. 6 results in a continuous surface with lower defect density that is suitable for subsequent epitaxial growth of layers that may be similar or dissimilar than the material of first epitaxial layer 900 of AIN. In the example embodiment, in addition to the higher quality first epitaxial layer 900, SiC substrate 100 comprises a plurality of voids 910 overlying regions of carbon comprising mask layer 800 of FIG. 8 formed between plurality of pillars 600 of FIG. 6. In the example embodiment, first epitaxial layer 900 comprising AIN has a lower density of defects compared to underlying patterned AIN layer 610 of FIG. 6 due to formation by epitaxial lateral overgrowth from sidewalls of plurality of pillars 600 of FIG. 6. The AIN growth from the sidewalls of adjacent pillars of the plurality of pillars 600 of FIG. 6 bridge together to form plurality of voids 910 overlying mask layer 800 of FIG. 8.

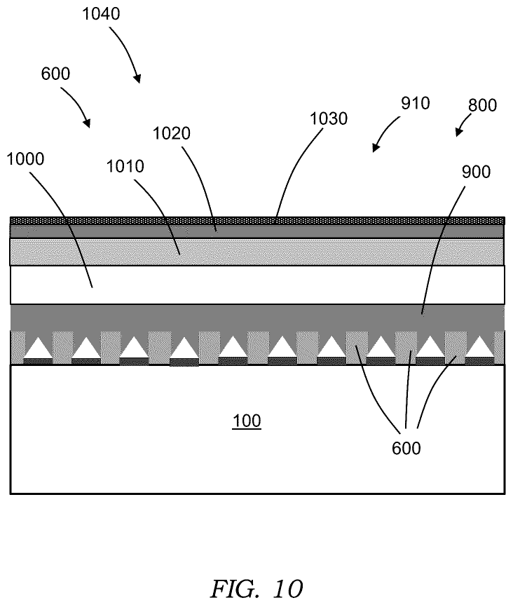

FIG. 10 is an illustration of epitaxial layers 1040 grown overlying first epitaxial layer 900, in accordance with an example embodiment. In the example embodiment first epitaxial layer 900 comprises AIN. Epitaxial layers 1040 overlying first epitaxial layer 900 may comprise one or more epitaxial layers that may comprise different material compositions, thicknesses and doping, to realize different semiconductor devices. For example, semiconductor devices that may be formed using epitaxial layers 1040 may be diodes, transistors, lasers, among other semiconductor devices. In an example embodiment, epitaxial layers 1040 are described with reference to an enhancement mode High Electron Mobility Transistor (e-mode HEMT) device. It should be noted that epitaxial layer 1040 can comprise a single epitaxial layer although in the example embodiment epitaxial layers 1040 comprises two or more epitaxial layers.

In an example embodiment, epitaxial layers 1040 for an e-mode HEMT comprise a second epitaxial layer 1000 comprising an AlGaN layer (Aluminum Gallium Nitride), an epitaxial layer comprising a GaN (Gallium Nitride) epitaxial layer 1010, an epitaxial layer comprising an AlGaN barrier layer 1020, and an epitaxial layer comprising a pGaN (positively doped GaN) layer 1030. In the example embodiment, second epitaxial layer 1000 comprising AlGaN layer grown overlying first epitaxial layer 900 of AIN forms a buffer layer that is closely lattice matched with underlying first epitaxial layer 900 of AIN. The buffer layer of AlGaN of high quality is grown overlying first epitaxial layer 900, because second epitaxial layer 1000 comprising AlGaN has a lattice structure that enables ordered crystalline growth of AlGaN. Second epitaxial layer 1000 of AlGaN overlying first epitaxial layer 900 of AIN is grown in an epitaxial reactor that enables epitaxial vertical overgrowth of AlGaN layer overlying first epitaxial layer 900. As noted, first epitaxial layer 900 of AIN is grown using epitaxial lateral overgrowth as described herein above.

In the example embodiment, epitaxial layer comprising a GaN epitaxial layer 1010 is grown overlying second epitaxial layer 1000 comprising AlGaN such that a transistor device such as a HEMT can be formed, as subsequently described herein.

The thickness and doping of epitaxial layer of GaN epitaxial layer 1010 are chosen to make it suitable for the fabrication of a HEMT, as will be evident to those skilled in the art.

In the example embodiment, epitaxial layer comprising an AlGaN barrier layer 1020 is grown overlying epitaxial layer of GaN epitaxial layer 1010. AlGaN barrier layer 1020 forms a barrier layer for the implementation of a HEMT device. The thickness and doping of epitaxial layer of AlGaN barrier layer 1020 causes a strain to be formed in the interface of GaN epitaxial layer 1010 and AlGaN barrier layer 1020 due to piezoelectric polarization resulting in an electric field. The lattice mismatch of the AlGaN barrier layer 1020 overlying GaN epitaxial layer 1010 causes strain resulting in an electric field across the interface. This results in a compensating 2DEG (Two Dimensional Electric Gas) region of electrons at the interface of GaN epitaxial layer 1010 underlying AlGaN barrier layer 1020. The 2DEG is used to efficiently conduct electrons when an electric field is applied across it. The 2DEG is highly conductive due to the confinement of the electrons to a very thin region at the interface and is used as the channel of the transistor that is subsequently formed. The confinement by the 2DEG increases the mobility of the electrons by at least 50% depending on the strain produced by AlGaN barrier layer 1020 overlying GaN epitaxial layer 1010. The increased mobility induced by the strain and the high concentration of the electrons enables the formation of the High Electron Mobility Transistor device.

In the example embodiment, epitaxial layer of pGaN (positively doped Gallium Nitride) layer 1030 is grown overlying AlGaN barrier layer 1020 used to form the 2DEG in GaN epitaxial layer 1010 for a HEMT device. Epitaxial layer comprising pGaN layer 1030 is doped by adding dopants such as Magnesium, Iron or other such dopants to a GaN layer. Epitaxial layer of pGaN layer 1030 is used to form a gate for a HEMT device so that the current flow in the channel formed by the 2DEG can be controlled or modulated as required. The epitaxial layer of pGaN layer 1030 produces a positive charge that has a built-in voltage that is larger than the voltage generated across the 2DEG by the strain induced piezoelectric effect and depletes the electrons in the 2DEG, thereby turning off the device. Thus, when the gate formed by epitaxial layer of pGaN layer 1030 is at zero voltage, the electrons in the channel formed by the 2DEG are depleted and the HEMT device is OFF. When the voltage applied on the gate formed by epitaxial layer of pGaN layer 1030 is positive, the channel is turned on by the electric field applied to the 2DEG and the HEMT device can conduct current across it by the application of a potential. In this case, the HEMT device is ON.

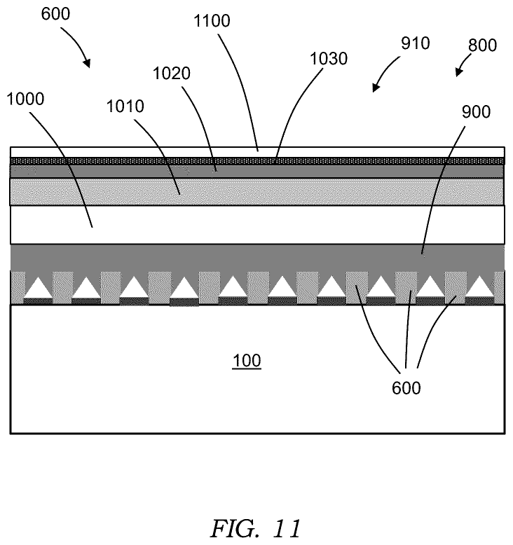

FIG. 11 is an illustration of a metal gate layer 1100 deposited over epitaxial layer of pGaN layer 1030, in accordance with an example embodiment. Metal gate layer 1100 is deposited over epitaxial layer of pGaN layer 1030 to form the gate of a HEMT device. Metal gate layer 1100 is deposited by e-beam evaporation and may comprise metals such as Nickel/Gold, Platinum or other suitable metal layers. Metal gate layer 1100 is formed overlying epitaxial layer of pGaN layer 1030 such that the channel of the 2DEG is depleted and the device is normally off when no voltage is applied on metal gate layer 1100.

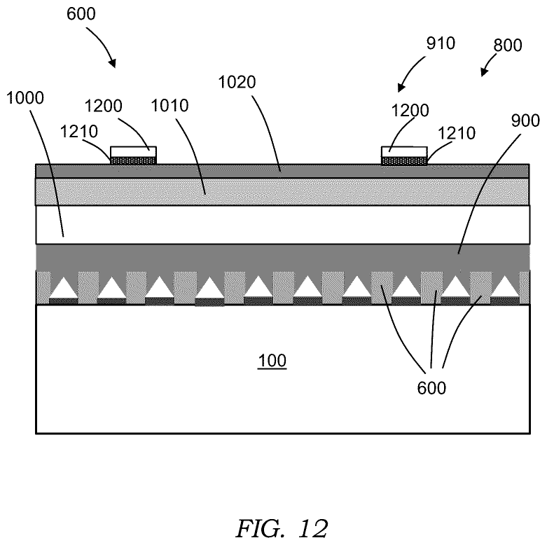

FIG. 12 is an illustration of transistor gate formed with patterned metal gate 1200 and patterned pGaN layer 1210 in accordance with an example embodiment.

Metal gate layer 1100 and epitaxial layer of pGaN layer 1030 in FIG. 11 are patterned to form the transistor gate of the HEMT. The transistor gate comprising patterned metal gate 1200 and patterned pGaN layer 1210 enables the control of charge carriers in the 2DEG GaN epitaxial layer 1010. The transistor gate comprising patterned metal gate 1200 and patterned pGaN layer 1210 is formed by etching metal gate layer 1100 and epitaxial layer of pGaN layer 1030 in FIG. 11. In one embodiment, a layer of photoresist is used to pattern metal gate layer 1100 by using RIE (Reactive Ion Etching) and then the patterned photoresist and patterned metal gate 1200 is then used to etch epitaxial layer of pGaN layer 1030 to form patterned pGaN layer 1210. In another embodiment, the patterning of metal gate layer 1100 is done using wet etchants. In another embodiment, the method of lift-off is used to form patterned metal gate 1200 and then RIE is used to form patterned pGaN layer 1210. After patterning and etching patterned metal gate 1200 and patterned pGaN layer 1210, the photoresist is removed.

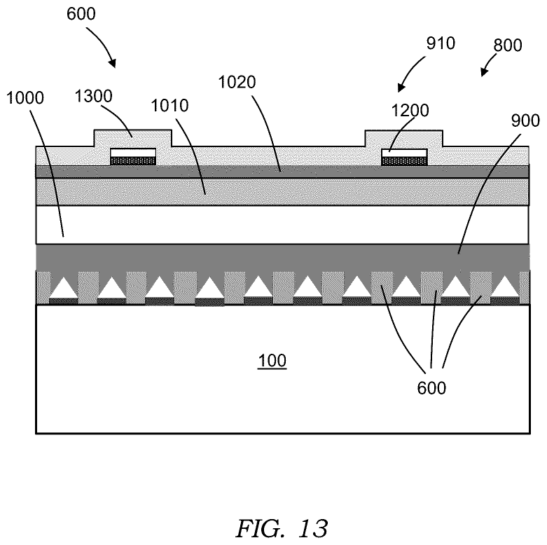

FIG. 13 is an illustration of an insulating layer 1300 deposited over the transistor gate formed with patterned metal gate 1200 and patterned pGaN layer 1210 in accordance with an example embodiment. In the example embodiment, insulating layer 1300 is formed with a PECVD layer that is low temperature and compatible with patterned metal gate 1200. In an example embodiment, insulating layer 1300 is formed by a PECVD oxide with a thickness between (0.5-2) micrometers. In another example embodiment, insulating layer 1300 is formed with PECVD PSG, BPSG, TEOS, among other materials. Insulating layer 1300 may be formed with other deposition technique such as PACVD (Plasma Assisted Chemical Vapor Deposition), LACVD (Laser Assisted Chemical Vapor Deposition), SACVD (Sub Atmospheric Chemical Vapor Deposition), APCVD (Atmospheric Pressure Chemical Vapor Deposition), sputtering among other deposition techniques. Insulating layer 1300 may also comprise materials such as silicon nitride, silicon oxynitride, among other materials.

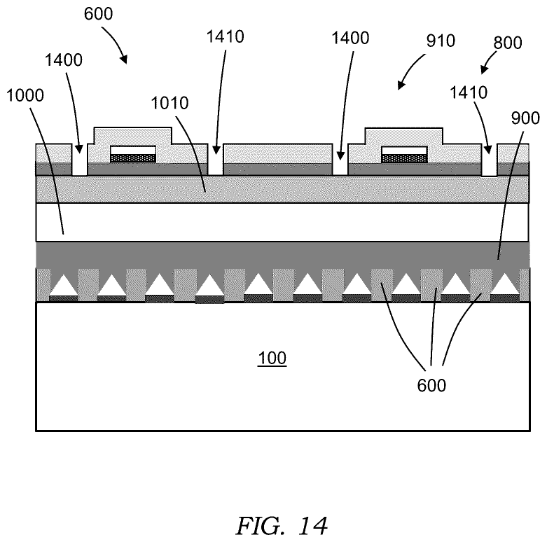

FIG. 14 is an illustration of contact openings formed in insulating layer 1300 in accordance with an example embodiment. In the example embodiment, the contact openings are formed by removing portions of insulating layer 1300 and AlGaN barrier layer 1020 to expose portions of GaN epitaxial layer 1010. In the example embodiment, source contact 1400 opens regions of contact to the source regions of the HEMTs and drain contact opening 1410 opens regions of contact to the drain regions of the HEMTs. In the example embodiment, contact openings to the gate region of the HEMTs are not shown in FIG. 14. In the example embodiment, source contact openings 1400 and drain contact openings 1410 are formed by patterning and etching insulation layer 1300 and underlying regions of AlGaN barrier layer 1020 to expose portions of GaN epitaxial layer 1010. In an example embodiment, insulating layer 1300 comprising PECVD oxide is etched using RIE using fluorine chemistry such as CHF₃, SF₆ among other process gases.

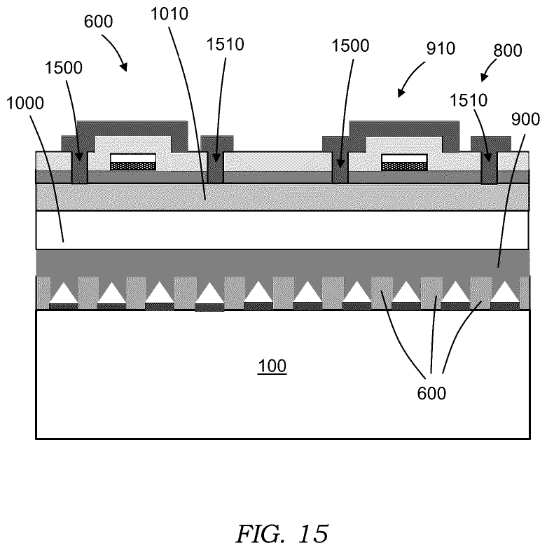

FIG. 15 is an illustration of metal contacts coupled to the source and drain regions of the HEMT in accordance with an example embodiment. In the example embodiment, source contact openings 1400 and drain contact openings 1410 are filled with deposited metal and patterned to form source contacts 1500 and drain contact 1510 as shown in FIG. 15. In the example embodiment, source contact openings 1400 and drain contact openings 1410 are filled with deposition of Aluminum by sputtering which is then patterned and etched to form source contacts 1500 and drain contact 1510. In another embodiment, source contact openings 1400 and drain contact openings 1410 are filled with deposition of Aluminum by e-beam evaporation. In another embodiment, source contact openings 1400 and drain contact openings 1410 are filled by forming tungsten plugs which are then combined with patterned aluminum metal to form source contacts 1500 and drain contacts 1510. Source contacts 1500 and drain contact 1510 may be formed by single layer metal, multiple layers of metal or metal with a barrier layer. Similarly, gate contacts are formed by filling gate contact openings by deposition and patterning of metal such as aluminum but not shown in FIG. 15. In the example embodiment, in FIG. 15, metal used to form source contact 1500 may also be used to form a field plate to reduce the capacitance coupling between the gate and drain of the HEMT.

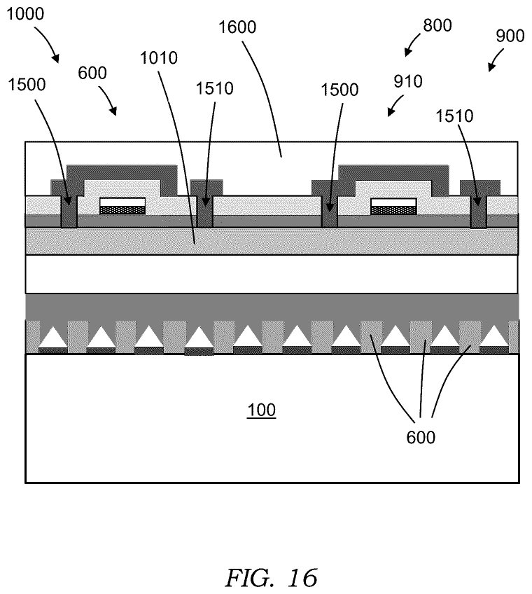

FIG. 16 is an illustration of an insulating layer 1600 formed over source contacts 1500 and drain contacts 1510 in accordance with an example embodiment. In the example embodiment, insulating layer 1600 is formed with a PECVD layer that is low temperature. In an example embodiment, insulating layer 1600 is formed by a PECVD oxide with a thickness between (0.5-2) micrometers. In another example embodiment, insulating layer 1600 is formed with PECVD PSG, BPSG, TEOS, among other materials. Insulating layer 1600 may be formed with other deposition technique such as PACVD (Plasma Assisted Chemical Vapor Deposition), LACVD (Laser Assisted Chemical Vapor Deposition), SACVD (Sub Atmospheric Chemical Vapor Deposition), APCVD (Atmospheric Pressure Chemical Vapor Deposition), sputtering among other deposition techniques. Insulating layer 1600 may also comprise materials such as silicon nitride, silicon oxynitride, among other materials. Insulating layer 1600 may comprise one layer or multiple layers of insulating material.

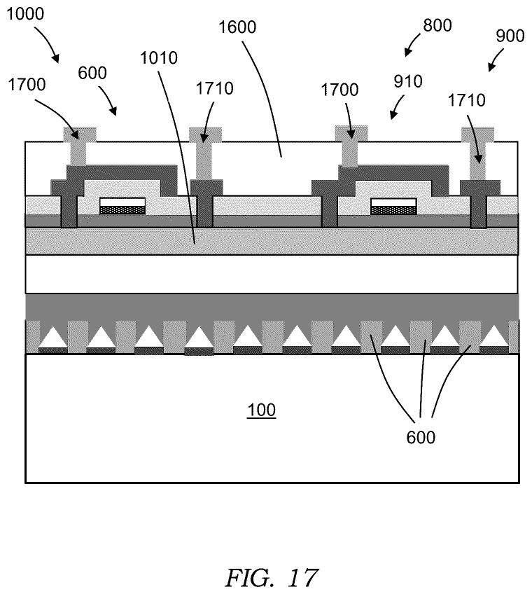

FIG. 17 is an illustration of second source metal contacts 1700 and second drain metal contacts 1710 formed in accordance with an example embodiment. In the example embodiment, insulating layer 1600 formed over source contacts 1500 and drain contacts 1510 is patterned and etched to form vias. In the example embodiment, Insulating layer 1600 comprising PECVD oxide is patterned and etched using RIE forming vias to expose underlying portions of source contacts 1500 and drain contacts 1510. The vias formed in insulating layer 1600 are then filled with another metal layer, such as aluminum, which is then patterned and etched to form second source metal contacts 1700 and second drain metal contacts 1710. Second source metal contacts 1700 and second drain metal contacts 1710 may also be formed by deposition and etching of multiple layers of metal including barrier metals. In addition to forming second source metal contacts 1700 and second drain metal contacts 1710, gate metal contacts can also be formed using the same metal layer but not shown in FIG. 17. Similarly, a second gate metal contact could be formed to couple to the gate contact if required.

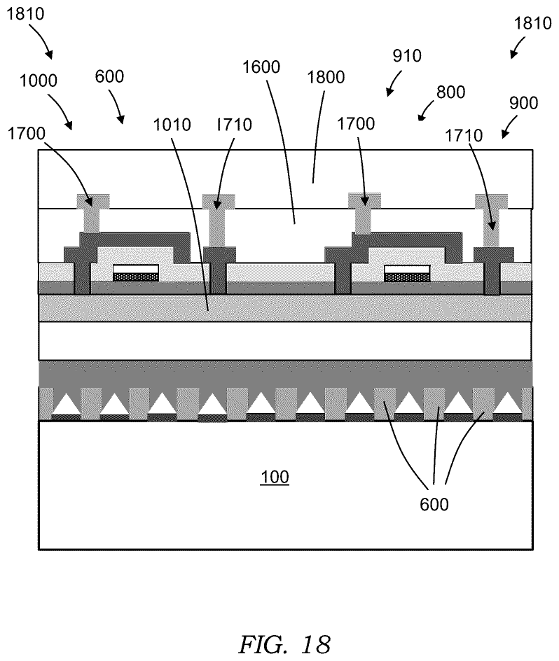

FIG. 18 is an illustration of a plurality of GaN devices 1810 formed in accordance with an example embodiment. In the example embodiment, plurality of GaN devices 1810 comprises HEMT (High Electron Mobility Transistor) devices formed in the epitaxial layers comprising multiple GaN layers, AIN layers and silicon carbide substrate.

In the example embodiment, a passivation layer 1800 is deposited over second source metal contacts 1700 and second drain metal contacts 1710 and patterned and etched to expose bond pads resulting in the formation of plurality of GaN devices 1810. In the example embodiment, passivation layer 1800 comprises a PECVD deposited layer such as silicon oxide, silicon nitride, silicon oxynitride, PSG, BPSG among other materials. Passivation layer 1800 may have a thickness between (1-3) micrometers and is meant to protect and passivate surface of plurality of GaN devices 1810 from external environmental factors such as moisture and particles. In another embodiment, passivating layer 1800 may be covered by another protective layer of polyimide that is patterned to expose the bond pads of plurality of GaN devices 1810.

In FIG. 18, while two GaN devices of plurality of GaN devices 1810 are shown, it will be understood by those skilled in the art that many GaN devices can be formed across the surface of one wafer simultaneously using the same design and fabrication process, as described in the example embodiment. In one embodiment, the process or steps described herein above result in the epitaxial layer in which GaN devices 1810 are formed have a defect density less than 10⁹/cm^{2.}

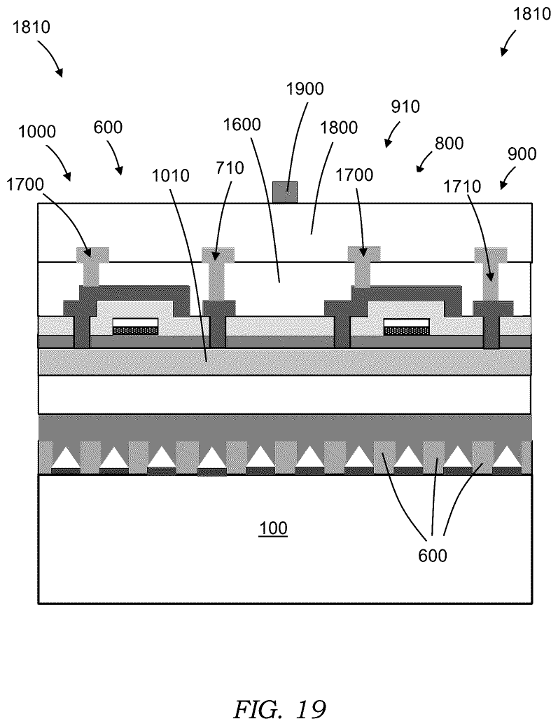

FIG. 19 is an illustration of a singulation layer 1900 formed over plurality of GaN devices 1810 in accordance with an example embodiment. In the example embodiment, singulation layer 1900 is formed over passivation layer 1800 and is formed to enable separation of individual GaN devices from plurality of GaN devices 1810 as formed on a complete wafer or substrate. In the example embodiment, singulation layer 1900 is formed by the deposition of a carbon layer that is selectively patterned over passivation layer 1800 between adjacent GaN devices of plurality of GaN devices 1810. In the example embodiment, singulation layer 1900 comprises a sputtered carbon layer deposited over surface of passivation layer 1800 and then patterned using oxygen plasma etching. In another embodiment, singulation layer 1900 is formed by PECVD deposition of a carbon layer. In another embodiment, singulation layer 1900 is formed by using carbon lift-off. Singulation layer 1900 is used with a laser to separate plurality of GaN devices 1810 with selectively coupling of thermal energy as described subsequently herein.

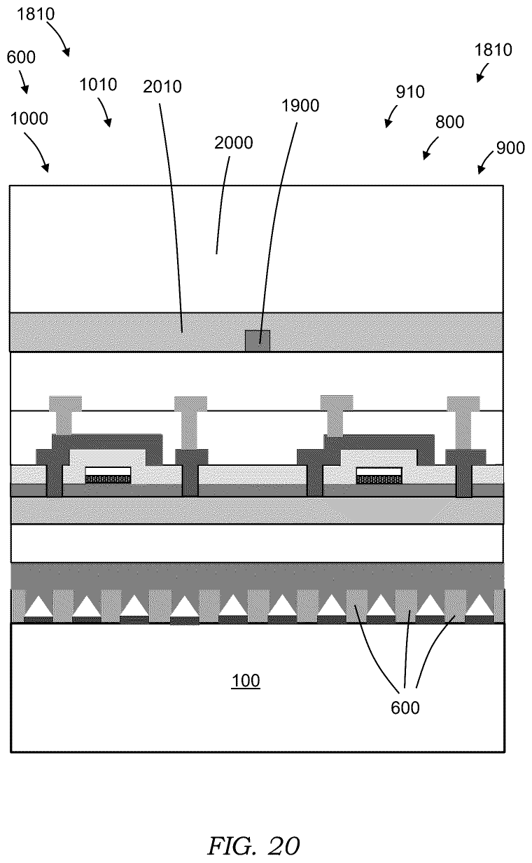

FIG. 20 is an illustration of a carrier substrate 2000 temporarily coupled to substrate 100 with the plurality of GaN devices 1810 in accordance with an example embodiment. Carrier substrate 2000 is temporarily coupled to SiC substrate 100 with at least one GaN epitaxial layer forming plurality of GaN devices 1810 using an adhesion layer 2010.

Plurality of GaN devices 1810 formed on at least GaN epitaxial layer overlying SiC substrate 100 is temporarily coupled to or mounted on carrier substrate 2000 to enable an exfoliation or separation process that is subsequently described. The exfoliation process enables the separation of plurality of GaN devices 1810 formed on at least GaN epitaxial layer to be separated from substrate 100 comprising silicon carbide and reuse of substrate 100 for repeating the formation of GaN devices as disclosed herein on substrate 100 after separation. Substrate 100 would require further preparation before being reused.

Carrier substrate 2000 coupled to plurality of GaN devices 1810 may comprise borosilicate glass which is UV transparent. Adhesion layer 2010 used for coupling carrier substrate 2000 to plurality of GaN devices 1810 may comprise an adhesive that is sensitive to UV light, among others. In another embodiment, adhesion layer 2010 may be sensitive to IR (Infrared) light and carrier substrate 2000 may comprise a semiconductor wafer comprising silicon, SiC, GaN, among other substrates. In an example embodiment, carrier substrate 2000 comprises a UV transparent borosilicate glass wafer and adhesion layer 2010 comprises a UV curable adhesive to enable a temporary bonding of carrier substrate 2000 to plurality of GaN devices 1810.

The exfoliation process occurs at an exfoliation layer that comprises plurality of pillars 600 of FIG. 6 in patterned AIN layer 610 of FIG. 6 and mask layer 800 of FIG. 8. In the example embodiment, plurality of pillars 600 of FIG. 6 comprise AIN and mask layer 800 of FIG. 8 formed between plurality of pillars 600 of FIG. 6 comprise carbon.

In one embodiment, a plane of the exfoliation layer is substantially parallel to the surface of substrate 100. In one embodiment, the exfoliation occurs above the surface of substrate 100. In the example embodiment, the plane of exfoliation will occur at approximately mask layer 800 of FIG. 8 comprising carbon formed between plurality of pillars 600 of FIG. 6 comprising AIN (aluminum nitride). In the example embodiment, the exfoliation process does not affect or damage substrate 100 which comprises SiC.

Different methods of exfoliation may be used to separate plurality of GaN devices 1810 formed on at least one GaN epitaxial layer from substrate 100. In the example embodiment, a laser may be used for the exfoliation process. In the example embodiment, the laser wavelength is chosen to be substantially transparent to SiC. In the example embodiment, the laser is focused from the backside of substrate 100 to deliver energy to mask layer 800. In one embodiment, the energy from the laser heats mask layer 800 of FIG. 8 over a very short time period. In addition to the laser light, mechanical force or torque may be applied to SiC substrate 100 and carrier substrate 2000 to facilitate separation.

In the example embodiment, the energy from the one or more lasers illuminating from the backside of SiC substrate 100 is selectively coupled to mask layer 800 comprising carbon. The laser energy rapidly heats the carbon of mask layer 800 producing a thermal shock that fractures plurality of pillars 600 comprising AIN adjacent to the heated carbon. The fracturing of plurality of pillars 600 due to thermal shock causes the separation of plurality of GaN devices 1810 with at least one GaN epitaxial layer from substrate 100. It should be noted that while the thermal shock fractures the plurality of pillars, the heat dissipates quickly and does not affect SiC substrate 100. In addition to thermal shock using a laser, mechanical force or torque may be applied to SiC substrate 100, carrier substrate 2000 or both to support the separation or exfoliation.

In the example embodiment, plurality of GaN devices 1810 with at least one GaN epitaxial layer coupled to carrier substrate 2000 is physically separated from SiC substrate 100 by the exfoliation process. The silicon carbide wafer in its entirety is separated from plurality of GaN devices 1810 with at least one GaN epitaxial layer such that the substrate 100 can be prepared and then reused for the formation of other devices or GaN HEMT devices as disclosed herein.

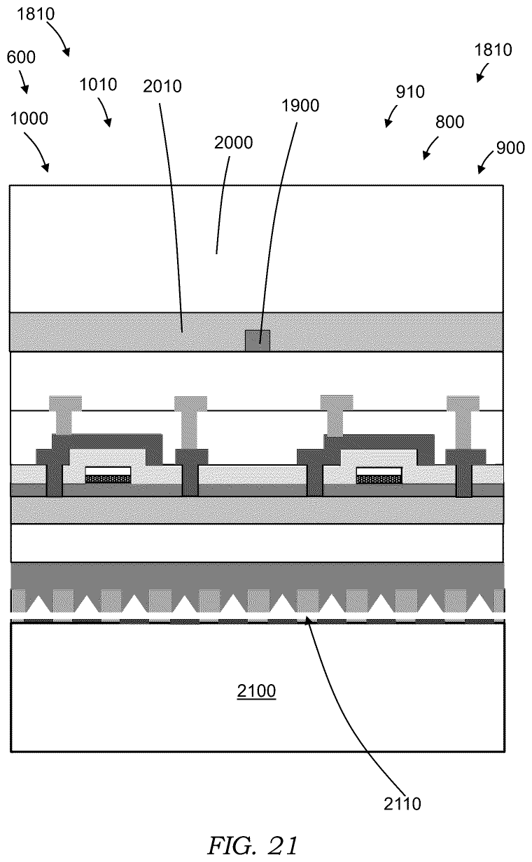

FIG. 21 is an illustration of plurality of GaN devices 1810 exfoliated from substrate 100 in accordance with an example embodiment. In the example embodiment, using a laser applied through substrate 100 causes the separation of a portion comprising plurality of GaN devices 1810 attached to carrier substrate 2000 from substrate 100 along a fracture along an exfoliation plane 2110. Exfoliation plane 2110 causes the cleaving of the exfoliated device comprising plurality of GaN devices 1810 temporarily attached to carrier substrate 2000 from separated SiC substrate 2100. A combination of thermal shock and mechanical force or torque may be used to enable the exfoliation process along exfoliation plane 2110. Thus, the exfoliation process yields plurality of GaN devices 1810 temporarily attached to carrier substrate 2000 and a new substrate comprising substrate 100 coupled to remnants of plurality of pillars 600 of FIG. 20. FIG. 21 is not drawn to scale since the exfoliated device comprising plurality of GaN devices 1810 may be in the range of 5-20 micrometers while separated SiC substrate 2100 produced by the exfoliation process is substantially the same thickness as initial SiC substrate 100 of FIG. 1 and is in the range of 300-500 micrometers. The exfoliation process described herein above separates the entire wafer with plurality of GaN devices 1810 from SiC substrate 100 of FIG. 1.

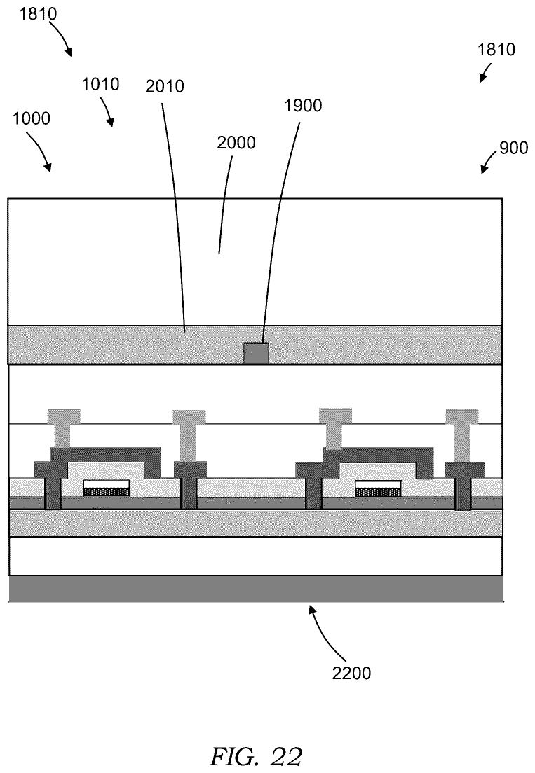

FIG. 22 is an illustration of the exfoliated device comprising plurality of GaN devices 1810 attached to carrier substrate 2000 in accordance with an example embodiment. In the example embodiment, after the exfoliation process, exfoliated devices comprising plurality of GaN devices 1810 attached to carrier substrate 2000 may have some remnants of plurality of pillars 600 coupled to first epitaxial layer 900. The remnants of plurality of pillars 600 of FIG. 6 coupled to first epitaxial layer comprising AIN is removed by polishing thereby resulting in a polished surface 2200 of first epitaxial layer 900 comprising AIN. The removal process may use CMP (Chemical Mechanical Planarization) resulting in polished surface 2200 of first epitaxial layer 900.

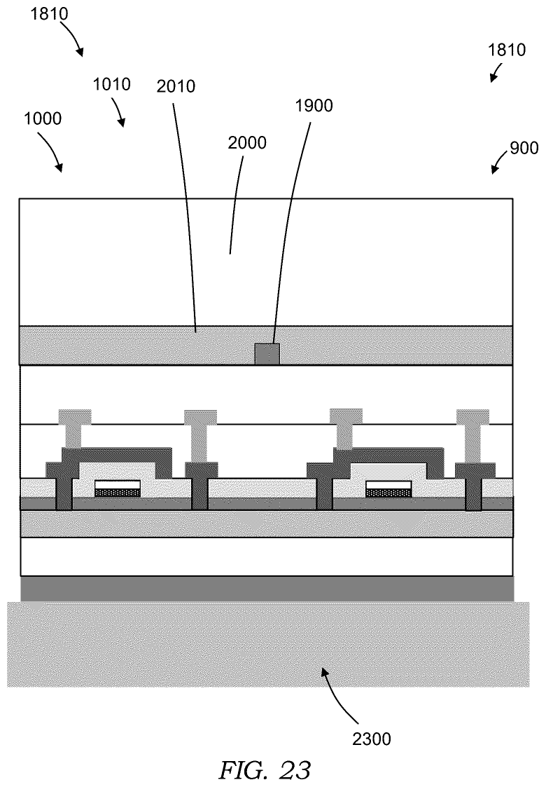

FIG. 23 is an illustration of the exfoliated device comprising plurality of GaN devices 1810 temporarily attached to carrier substrate 2000 in accordance with an example embodiment. In the example embodiment, after the polishing of first epitaxial layer 900 comprising AIN resulting in polished surface 2200 of FIG. 22, the plurality of GaN devices 1810 is temporarily attached to carrier substrate 2000 and mounted on a dicing tape 2300 in preparation to singulate or separate plurality of GaN devices 1810 into individual devices or die. The mounting process to dicing tape 2300 is done using industry standard adhesives well known to those skilled in the art.

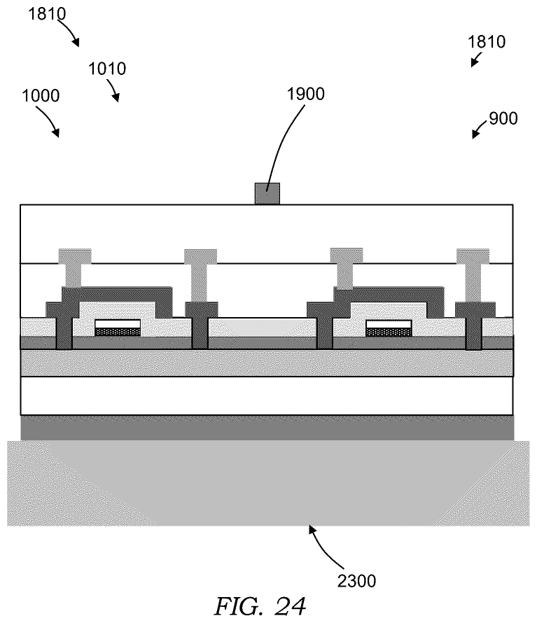

FIG. 24 is an illustration of the exfoliated device comprising plurality of GaN devices 1810 after being separated from carrier substrate 2000 in accordance with an example embodiment. In the example embodiment, UV (ultra violet) light is used to separate carrier substrate 2000 from exfoliated device comprising plurality of GaN devices 1810. Plurality of GaN devices 1810 remain mounted on dicing tape 2300. It should be noted that while two GaN devices are shown, other GaN devices were formed simultaneously across the entire epitaxial layer or layers. Typically, plurality of GaN devices 1810 comprise hundreds or thousands of devices, depending on the substrate size.

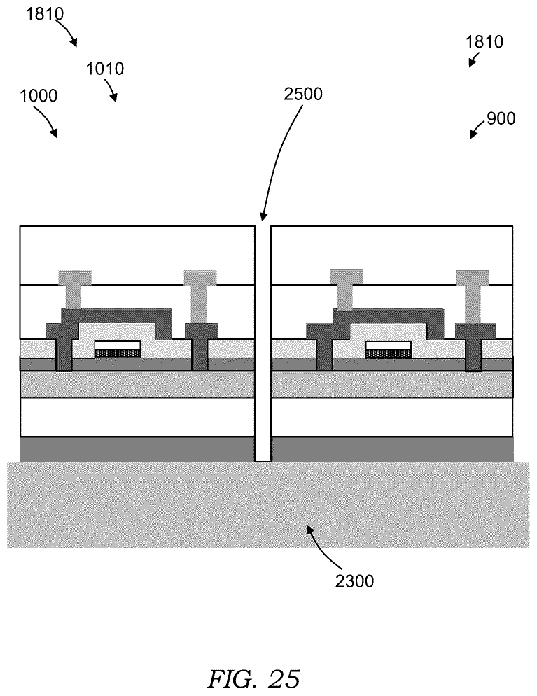

FIG. 25 is an illustration of plurality of GaN devices 1810 after singulation in accordance with an example embodiment. In the example embodiment, the singulation or separation of plurality of GaN devices 1810 into individual die using singulation layer 1900 comprising carbon. A laser is used to couple thermal energy selectively to the carbon of singulation layer 1900 causing thermal shock resulting in a scribe line 2500 between individual adjacent devices of plurality of GaN devices 1810. Scribe line 2500 causes a vertical fracture of the epitaxial layers used for formation of plurality of GaN devices 1810 as described earlier herein. While one scribe line 2500 is shown with two individual GaN devices of a plurality of GaN devices 1810 attached to dicing tape 2300, it will be understood that the singulation process will result in hundreds or thousands of separate devices attached to dicing tape 2300, depending on the substrate size. In another embodiment, scribe line 2500 may be formed by laser dicing or dicing saw. In the example embodiment, GaN devices 1810 are separated into separate die. It should be noted that the technique disclosed herein using singulation layer 1900 is not limited to GaN devices but can be used on other substrates, epitaxial layers, or devices of different types. Singulation layer 1900 is shown in a single direction but singulation 1900 can be patterned in different directions across the entire epitaxial layer or layers. For example, singulation layer can be patterned in both the X and Y directions thereby cutting the die in squares or rectangles around the perimeter of each device. The die during singulation are held in place by the dicing tape 2300.

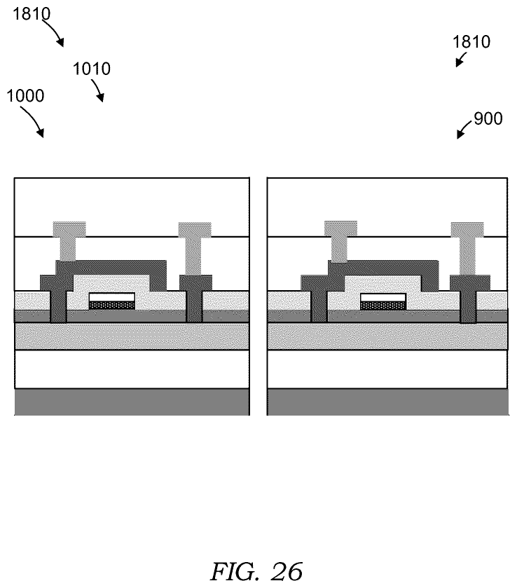

FIG. 26 is an illustration of plurality of GaN devices 1810 after removal from dicing tape 2300 in accordance with an example embodiment. In the example embodiment, after the singulation process using singulation layer 1900, the plurality of GaN devices 1810 are removed from dicing tape 2300 to form individual GaN devices. The individual GaN devices removed from dicing tape 2300 are then assembled in packages to be used for various applications.

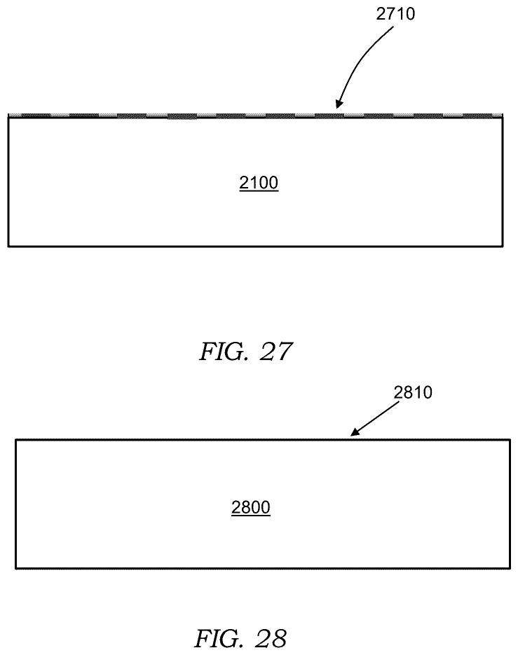

FIG. 27 is an illustration of separated substrate 2100 from FIG. 21 after the exfoliation process in accordance with an example embodiment. In the example embodiment, separated substrate 2100 from FIG. 21 comprises a portion of substrate 100 of FIG. 20 along with remnants of plurality of pillars 600 of FIG. 20. In the example embodiment, substrate 2100 comprises SiC. In the example embodiment, remnants of plurality of pillars 600 of FIG. 20 comprise AIN that forms a surface 2710 of separated SiC substrate 2100.

FIG. 28 is an illustration of a new substrate 2800 in accordance with an example embodiment. In the example embodiment, new substrate 2800 is formed by reclaiming separated substrate 2100 of FIG27. In one embodiment, the removal of remnants of plurality of pillars 600 of FIG. 20 comprising AIN is accomplished by CMP (Chemical Mechanical Planarization). This results in polished surface 2810 of new substrate 2800. In addition to the removal of remnants of plurality of pillars 600 of FIG. 20 comprising AIN, a portion of a surface of separated substrate 2100 of FIG. 27 may also be removed to form polished surface 2810. New substrate 2800 may be used two or more times to form plurality of GaN devices 1810 of FIG. 26 by using the epitaxial growth of at least one GaN layer as described earlier herein. In the example embodiment, new substrate 2800 comprising SiC can be used as a substrate to form GaN devices as disclosed herein or be used to form other device types.

While the present invention has been described with reference to certain preferred embodiments or methods, it is to be understood that the present invention is not limited to such specific embodiments or methods. Rather, it is the inventor's contention that the invention be understood and construed in its broadest meaning as reflected by the following claims. Thus, these claims are to be understood as incorporating not only the preferred methods described herein but all those other and further alterations and modifications as would be apparent to those of ordinary skilled in the art.

The descriptions disclosed herein below will call out components, materials, inputs, or outputs from FIGS. 1-28.

In one embodiment, a plurality of GaN (gallium nitride) devices 1810 formed on a SiC (Silicon Carbide) substrate 100 comprises a patterned aluminum nitride layer 610 overlying the SiC substrate 100 wherein portions of SiC substrate 100 is exposed, a mask layer 800 placed on the exposed portions of SiC substrate 100, a first epitaxial layer 900 of aluminum nitride formed overlying the patterned aluminum nitride layer 610 wherein the first epitaxial layer 900 is formed by epitaxial lateral overgrowth, a second epitaxial layer 1000 of aluminum gallium nitride (AlGaN) formed overlying the first epitaxial layer 900 wherein the second epitaxial layer 1000 is formed by epitaxial vertical overgrowth, and at least one GaN epitaxial layer 1010 formed overlying the second epitaxial layer 1000 wherein the plurality of GaN devices 1810 are formed in or overlying the GaN epitaxial layer 1010 and wherein the mask layer 800 is configured to be heated to a temperature that produces a thermal shock to the patterned aluminum nitride layer 610 thereby at least partially separating the SiC substrate 100 from the one or more GaN devices.

In one embodiment, the plurality of GaN (gallium nitride) devices 1810 formed on a SiC (Silicon Carbide) substrate 100 wherein the mask layer 800 is less than a height 620 of the patterned aluminum nitride layer 610 and wherein the mask layer 800 comprises a material that is heated to produce a thermal shock that separates the SiC substrate 100 from the at least one GaN epitaxial layer 1010 such that the SiC substrate 100 is reuseable.

In one embodiment, the plurality of GaN (gallium nitride) devices 1810 wherein the patterned aluminum nitride layer 610 comprises a plurality of pillars 600 formed over substantially an entire surface of the SiC substrate 100.

In one embodiment, the plurality of GaN (gallium nitride) devices 1810 wherein a surface of the first layer 200 of aluminum nitride overlies substantially the entire surface of the SiC substrate 100 and wherein a void 910 is formed between the surface of the first layer 200 of aluminum nitride and the mask layer 800.

In one embodiment, the plurality of GaN (gallium nitride) devices 1810 wherein the material of the mask layer 800 comprises carbon, tantalum carbide, or a material that is converted to carbon.

In one embodiment, the plurality of GaN (gallium nitride) devices 1810 wherein a carrier substrate 2000 is coupled to the at least one GaN epitaxial layer 1010.

In one embodiment, the plurality of GaN (gallium nitride) devices 1810 wherein one or more lasers is configured to heat the mask layer 800 through the SiC substrate 100 to produce the thermal shock.

In one embodiment, the plurality of GaN (gallium nitride) devices 1810 wherein a force or torque is applied to the SiC substrate 100, the carrier substrate 2000, or both to support separation.

In one embodiment, the plurality of GaN (gallium nitride) devices 1810 comprises RF (radio frequency) GaN devices, HEMT (high-electron-mobility-transistors) devices, or (UV) ultra violet light emitting diode devices.

In one embodiment, the plurality of GaN (gallium nitride) devices 1810 wherein a surface 2710 of a separated SiC substrate 2100 is configured to be polished to create a new SiC substrate 2800 that is configured for reuse to manufacture one or more semiconductor devices.

In one embodiment, the plurality of GaN (gallium nitride) devices 1810 wherein the at least one GaN epitaxial layer 1010 is coupled to dicing tape 2300, wherein the carrier substrate 2000 is removed, and wherein the one or more GaN devices are configured to be singulated and packaged.

In one embodiment, a plurality of GaN (gallium nitride) devices 1810 formed on a SiC (Silicon Carbide) substrate 100 comprises a plurality of aluminum nitride (AIN) pillars overlying the SiC substrate 100 wherein the SiC substrate 100 is exposed between adjacent pillars of the plurality of pillars 600, a mask layer 800 placed on the exposed portions of the SiC substrate 100, a first epitaxial layer 900 of aluminum nitride formed overlying the patterned aluminum nitride layer 610 wherein the first epitaxial layer 900 is formed by epitaxial lateral overgrowth, at least a second epitaxial layer 1000 of Aluminum Gallium Nitride formed overlying the first epitaxial layer 900 wherein the second epitaxial layer 1000 is formed by epitaxial vertical overgrowth, and at least one GaN epitaxial layer 1010 formed overlying the second epitaxial layer 1000 wherein the plurality of GaN devices 1810 are formed in or overlying the GaN epitaxial layer 1010, wherein the mask layer 800 is configured to be heated by at least one laser through the SiC substrate 100 to a temperature that produces a thermal shock to the plurality of aluminum nitride pillars thereby at least partially separating the SiC substrate 100 from the one or more GaN devices, and wherein a separated SiC substrate 2100 is configured for reuse by performing at least one chemical-mechanical planarization step to form a new SiC substrate 2800.

In one embodiment, the plurality of GaN (gallium nitride) devices 1810 wherein the mask layer 800 comprises carbon or tantalum carbide prior to heating with the laser, wherein the mask layer 800 is below a height 620 of the plurality of aluminum nitride pillars, and wherein a void 910 is formed overlying the mask layer 800 after the first epitaxial layer 900 is formed by the epitaxial lateral overgrowth.

In one embodiment, the plurality of GaN (gallium nitride) devices 1810 comprises RF (radio frequency) GaN devices, HEMT (high-electron-mobility-transistors) devices, or (UV) ultra violet light emitting diode devices.

In one embodiment, the plurality of GaN (gallium nitride) devices 1810 further includes a carrier substrate 2000 coupled to the plurality of GaN devices 1810 wherein the at least one laser is configured to heat the mask layer 800 that produces the thermal shock to weaken or fracture the plurality of aluminum nitride pillars of the first epitaxial layer 900.

In one embodiment, the plurality of GaN (gallium nitride) devices 1810 wherein a torque or force is configured to be applied to the carrier substrate 2000, the silicon carbide substrate 100, or both, wherein the torque or force separates the silicon carbide substrate 100 from the plurality of GaN devices 1810, and wherein the GaN devices are singulated and packaged.

In one embodiment, a method of forming a plurality of GaN (gallium nitride) devices 1810 formed on a SiC (Silicon Carbide) substrate 100 comprises forming a plurality of aluminum nitride (AIN) pillars overlying the SiC substrate 100 that exposes the SiC substrate 100 between each pillar of the plurality of aluminum nitride pillars, forming a mask layer 800 that couples to the SiC substrate 100 and has a height 620 less than the plurality of aluminum nitride pillars, growing a first epitaxial layer 900 of aluminum nitride overlying the plurality of aluminum nitride pillars by epitaxial lateral overgrowth such that the first epitaxial layer 900 has a continuous surface overlying the SiC substrate 100, growing at least a second epitaxial layer 1000 of Aluminum Gallium Nitride overlying the first epitaxial layer 900 wherein the second epitaxial layer 1000 is formed by epitaxial vertical overgrowth, and forming at least one GaN epitaxial layer 1010 overlying the second epitaxial layer 1000, forming a plurality of GaN devices 1810 in or overlying the GaN epitaxial layer 1010 wherein the plurality of GaN devices 1810 comprises RF (radio frequency) GaN devices, HEMT (high-electron-mobility-transistors) devices, or (UV) ultra violet light emitting diode devices, coupling a carrier substrate 2000 to the plurality of GaN devices 1810, heating the mask layer 800 to create a thermal shock that weakens or fractures the plurality of aluminum nitride pillars, separating the plurality of GaN devices 1810 from SiC substrate 100, and reusing the SiC substrate 100 to form at least one semiconductor device.

In one embodiment, the method of forming a plurality of GaN (gallium nitride) devices 1810 formed on a SiC (Silicon Carbide) substrate 100 further includes applying a force or torque to separate the plurality of GaN devices 1810 from the SiC substrate 100, removing the carrier substrate 2000 from the plurality of GaN devices 1810, dicing the plurality of GaN devices 1810, and packaging the plurality of GaN devices 1810.

In one embodiment, the method of forming a plurality of GaN (gallium nitride) devices 1810 formed on a SiC (Silicon Carbide) substrate 100 further includes removing the remaining plurality of aluminum nitride pillars from the SiC substrate after separation, planarizing, and polishing the SiC substrate to form a new surface on the SiC substrate.

In one embodiment, the method of forming a plurality of GaN (gallium nitride) devices 1810 formed on a SiC (Silicon Carbide) substrate 100 further includes forming a plurality of devices in, on, or overlying the new surface of the SiC substrate.

1. A plurality of GaN (gallium nitride) devices formed on a SiC (Silicon Carbide) substrate comprising:
a patterned aluminum nitride layer overlying the SiC substrate wherein portions of the SiC substrate is exposed;
a mask layer placed on the exposed portions of the SiC substrate;
a first epitaxial layer of aluminum nitride grown overlying the patterned aluminum nitride layer wherein the first epitaxial layer is formed by epitaxial lateral overgrowth;
a second epitaxial layer of Aluminum Gallium Nitride formed overlying the first epitaxial layer wherein the second epitaxial layer is formed by epitaxial vertical overgrowth; and
at least one GaN epitaxial layer grown overlying the second epitaxial layer wherein the plurality of GaN devices are formed in or overlying the GaN epitaxial layer.

2. The plurality of GaN (gallium nitride) devices of claim 1 wherein the patterned aluminum nitride layer is formed by etching an aluminum nitride layer overlying the SiC substrate.

3. The plurality of GaN (gallium nitride) devices of claim 1 wherein the patterned aluminum nitride layer comprises a plurality of pillars.

4. The plurality of GaN (gallium nitride) devices of claim 1 wherein a surface of the first epitaxial layer of aluminum nitride overlies the surface of the SiC substrate.

5. The plurality of GaN (gallium nitride) devices of claim 1 wherein the material of the mask layer comprises carbon or tantalum carbide.

6. The plurality of GaN (gallium nitride) devices of claim 5 wherein the carbon of the mask layer comprises a polymer converted to the carbon by pyrolysis.

7. The plurality of GaN (gallium nitride) devices of claim 1 wherein the mask layer is less than a height of the patterned aluminum nitride layer.

8. The plurality of GaN (gallium nitride) devices of claim 1 wherein at least one void is formed between the surface of the first epitaxial layer of aluminum nitride and the mask layer.

9. The plurality of GaN (gallium nitride) devices of claim 1 wherein the plurality of GaN devices comprises RF (radio frequency) GaN devices, HEMT (high-electron-mobility-transistors) devices, or (UV) ultra violet light emitting diode devices.

10. The plurality of GaN (gallium nitride) devices of claim 1 wherein the first epitaxial layer of aluminum nitride has lower defectivity than the patterned aluminum nitride layer to reduce the defectivity in the second epitaxial layer of Aluminum Gallium Nitride when grown on a surface of the first epitaxial layer of aluminum nitride.

11. The plurality of GaN (gallium nitride) devices of claim 10 wherein the first epitaxial layer of aluminum nitride is configured to reduce a propagation of defects such as threading dislocation or edge dislocations to the second epitaxial layer of Aluminum Gallium Nitride.

12. A plurality of GaN (gallium nitride) devices formed on a SiC (Silicon Carbide) substrate comprising:
a plurality of aluminum nitride (AIN) pillars overlying the SiC substrate wherein a surface of the SiC substrate is exposed between adjacent pillars of the plurality of pillars;
a mask layer placed on the exposed portions of the SiC substrate;
a first epitaxial layer of aluminum nitride formed overlying the patterned aluminum nitride layer wherein the first epitaxial layer is formed by epitaxial lateral overgrowth;
at least a second epitaxial layer of aluminum gallium nitride formed overlying the first epitaxial layer wherein the second epitaxial layer is formed by epitaxial vertical overgrowth; and
at least one GaN epitaxial layer formed overlying the second epitaxial layer wherein the plurality of GaN devices are formed in or overlying the GaN epitaxial layer.

13. The plurality of GaN (gallium nitride) devices of claim 12 wherein the mask layer comprises carbon or tantalum carbide and wherein the mask layer is below a height of each pillar of the plurality of aluminum nitride pillars.

14. The plurality of GaN (gallium nitride devices of claim 12 wherein the plurality of GaN devices comprises RF (radio frequency) GaN devices, HEMT (high-electron-mobility-transistors) devices, or (UV) ultra violet light emitting diode devices.

15. The plurality of GaN (gallium nitride devices of claim 12 wherein the first epitaxial layer of aluminum nitride has lower defectivity than the plurality of aluminum nitride pillars to reduce the defectivity in the second epitaxial layer of Aluminum Gallium Nitride when grown on a surface of the first epitaxial layer of aluminum nitride.

16. The plurality of GaN (gallium nitride devices of claim 15 wherein the first epitaxial layer of aluminum nitride is configured to reduce a propagation of defects such as threading dislocation or edge dislocations to the second epitaxial layer of Aluminum Gallium Nitride.

17. A method of forming a plurality of GaN (gallium nitride) devices on a SiC (Silicon Carbide) substrate comprising:
forming a plurality of aluminum nitride (AIN) pillars in an AIN layer overlying the SiC substrate wherein the SiC substrate is exposed between each pillar of the plurality of aluminum nitride pillars;
forming a mask layer that couples to the SiC substrate and has a height less than each pillar of the plurality of aluminum nitride pillars;
growing a first epitaxial layer of aluminum nitride overlying the plurality of aluminum nitride pillars by epitaxial lateral overgrowth such that the first epitaxial layer has a continuous surface overlying the SiC substrate;
growing at least a second epitaxial layer of aluminum gallium nitride overlying the first epitaxial layer wherein the second epitaxial layer is formed by epitaxial vertical overgrowth; and
growing at least one GaN epitaxial layer overlying the second epitaxial layer wherein the plurality of GaN devices are formed in or overlying the at least one GaN epitaxial layer.

18. The method of forming a plurality of GaN (gallium nitride) devices formed on a SiC (Silicon Carbide) substrate of claim 17 wherein the mask layer comprises carbon or tantalum carbide.

19. The method of forming a plurality of GaN (gallium nitride) devices formed on a SiC (Silicon Carbide) substrate of claim 17 wherein the first epitaxial layer of aluminum nitride has a lower defectivity than the plurality of aluminum nitride pillars and wherein the second epitaxial layer of aluminum gallium nitride is grown on a surface of the first epitaxial layer of aluminum nitride.

20. The method of forming a plurality of GaN (gallium nitride) devices formed on a SiC (Silicon Carbide) substrate of claim 19 wherein the first epitaxial layer of aluminum nitride is configured to reduce a propagation of defects such as threading dislocation or edge dislocations to the second epitaxial layer of Aluminum Gallium Nitride.
